(19) United States
(12) Patent Application Publication
(10) Pub. No.: US 2025/0271498 A1
(43) Pub. Date: Aug. 28, 2025

(54) TEST VEHICLES, SUCH AS TEST VEHICLES FOR SYSTEM-IN-PACKAGE INTEGRATION BRINGUP PROCESSES, AND ASSOCIATED SYSTEMS AND METHODS

(71) Applicant: Micron Technology, Inc., Boise, ID (US)

(72) Inventor: Rajesh H. Kariya, Boise, ID (US)

(21) Appl. No.: 19/043,421

(22) Filed: Feb. 1, 2025

Related U.S. Application Data
(60) Provisional application No. 63/558,081, filed on Feb. 26, 2024.

(51) Int. Cl. G01R 31/28

(52) U.S. Cl. CPC G01R 31/2889

(57) ABSTRACT

Systems and methods related to test vehicles, such as test vehicles for system-in-package (SiP) integration bringup processes, are disclosed herein. In one embodiment, a method includes integrating a first test vehicle and a second test vehicle with an interposer such that the first test vehicle is communicably coupled to the second test vehicle via a native communication channel in the interposer. Thereafter, the interposer is integrated with a package substrate, thereby communicably coupling the first and second test vehicles to access pins of the package substrate. An external testing device is coupled to the access pins and executes one or more tests, such as to assess compatibility between (a) SiP devices resembled by the interposer and the first and second test vehicles and (b) the package substrate and/or corresponding packaging processes.

### CROSS-REFERENCE TO RELATED APPLICATION(S) FIELD

The present application claims priority to U.S. Provisional Patent Application No. 63/558,081, filed Feb. 26, 2024, the disclosure of which is incorporated herein by reference in its entirety.

### TECHNICAL FIELD

The present technology is generally directed to semiconductor devices. For example, several embodiments of the present technology are directed to test vehicles and/or to associated methods of using test vehicles to characterize compatibility between (a) system-in-package (SiP) devices and (b) package substrates and/or corresponding packaging processes.

### BACKGROUND

An electronic apparatus (e.g., a processor, a memory device, a memory system, or a combination thereof) can include one or more semiconductor circuits configured to store and/or process information. For example, the apparatus can include a memory device, such as a volatile memory device, a non-volatile memory device, or a combination device. Memory devices, such as dynamic random-access memory (DRAM) and/or high-bandwidth memory (HBM), can utilize electrical energy to store and access data.

With technological advancements in embedded systems and increasing applications, the market is continuously looking for faster, more efficient, and smaller devices. To meet market demands, semiconductor devices are being pushed to the limit with various improvements. Improving devices, generally, may include increasing circuit density, increasing circuit capacity, increasing operating speeds (or otherwise reducing operational latency), increasing reliability, increasing data retention, reducing power consumption, or reducing manufacturing costs, among other metrics. Attempts, however, to meet market demands, such as by reducing the overall device footprint, can often introduce challenges in other aspects, such as maintaining circuit robustness and/or failure detectability.

### BRIEF DESCRIPTION OF THE DRAWINGS

Many aspects of the present disclosure can be better understood with reference to the following drawings. The components in the drawings are not necessarily to scale. Instead, emphasis is placed on illustrating clearly the principles of the present disclosure. The drawings should not be taken to limit the disclosure to the specific embodiments depicted, but are for explanation and understanding only.

FIGS. 1A and 1B are partially schematic views of an environment in which daisy chain test vehicles are used.

FIG. 2A is a partially schematic cross-sectional view of an environment configured in accordance with various embodiments of the present technology.

FIG. 2B is a partially schematic top plan view of the environment of FIG. 2A.

FIG. 3 is a flow diagram illustrating a process for testing compatibility of semiconductor components in accordance with various embodiments of the present technology.

FIG. 4A is a flow diagram illustrating a direct current signal test process in accordance with various embodiments of the present technology.

FIG. 4B is a flow diagram illustrating an alternating current signal test process in accordance with various embodiments of the present technology.

FIG. 4C is a flow diagram illustrating a die crack detection process in accordance with various embodiments of the present technology.

### DETAILED DESCRIPTION

As discussed in more detail below, the present disclosure is directed to test vehicles, such as for use in a system-in-package (SiP) integration bringup processes, and to associated systems and methods. For example, a test vehicle configured in accordance with the present technology can be constructed with circuits and/or other active components, such as components that are generally similar to the circuits and/or active components included in a high-bandwidth memory (HBM) device. As a specific example, a test vehicle of the present technology can be or include an HBM device that includes at least minimum basic functionality but that has been rejected (e.g., during quality control or another testing procedure) from being implemented into a customer product. Thus, continuing with this example and comparing the test vehicles of the present technology to daisy chain test vehicles (DCTVs) typically used in SiP integration bringup processes, the test vehicles of the present technology are expected to provide a more direct analog or better proxy (during SiP integration bringup processes) for fully functioning HBM devices implemented in a SiP device. Further, because each test vehicle of the present technology includes circuitry and other active components (e.g., at least generally similar to fully functional HBM devices), test vehicles of the present technology are expected to expand the number of different types of tests that can be performed during SiP integration processes. As a result, in comparison to DCTVs, test vehicles and associated SiP integration processes of the present technology are expected to enable more accurate assessment of whether components of a SiP device, a package substrate integrated with the SiP device, and/or corresponding packaging processes are compatible with one another.

Although systems and methods of the present technology are primarily discussed herein with reference to SiP integration processes and associated tests for confirming compatibility between SiP devices, package substrates, and/or packaging processes, one of skill in the art will understand that the present technology is not so limited. Purely by way of example, the repurposing of functional reject components in a proxy device can be used in an integration bringup process to confirm that the functional reject components (and/or fully functioning components represented by the functional reject components) are compatible with a base substrate of a SiP device simulated by the proxy device before considering whether the proxy device and/or a SiP device simulated by the proxy device is/are compatible with a package substrate or a broader package/component. Additionally, although specific functional tests are discussed below as part of SiP integration bringup processes of the present technology, one of skill in the art will understand that, because a test vehicle of the present technology can include various circuits and/or other active components (e.g., that are at least generally similar to those included in an HBM device), any other suitable tests can be implemented therein and are therefore considered within the scope of the present technology.

As used herein, the terms “vertical,” “lateral,” “upper,” “lower,” “top,” and “bottom” can refer to relative directions or positions of features in the devices in view of the orientation shown in the drawings. For example, “bottom” can refer to a feature positioned closer to the bottom of a page than another feature. These terms, however, should be construed broadly to include devices having other orientations, such as inverted or inclined orientations where top/bottom, over/under, above/below, up/down, and left/right can be interchanged depending on the orientation.

High data reliability, high speed of memory access, lower power consumption, and reduced chip size are features that are demanded from semiconductor memory. In recent years, three-dimensional (3D) memory devices have been introduced. Some 3D memory devices are formed by stacking memory dies vertically, and interconnecting the dies using through-silicon (or through-substrate) vias (TSVs). Benefits of the 3D memory devices include shorter interconnects (which reduce circuit delays and power consumption), a large number of vertical vias between layers (which allow wide bandwidth buses between functional blocks, such as memory dies, in different layers), and a considerably smaller footprint. Thus, the 3D memory devices contribute to higher memory access speed, lower power consumption, and chip size reduction. Example 3D memory devices include hybrid memory cubes (HMCs) and HBM devices. For example, HBM is a type of memory that includes a vertical stack of memory dies (e.g., dynamic random-access memory (DRAM) dies) and an interface die (which, e.g., provides an interface between the memory dies of the HBM device and a host device).

In a typical SiP device configuration, HBM devices may be integrated with a host device (e.g., a graphics processing unit (GPU), a computer processing unit (CPU), a tensor processing unit (TPU), and/or any other suitable processing unit) using a base substrate (e.g., a silicon interposer, a substrate of organic material, a substrate of inorganic material, and/or any other suitable material that provides interconnection between the host device and the HBM device and/or provides mechanical support for the components of a SiP device), through which the HBM devices and the host device communicate. Because traffic between the HBM devices and the host device resides within the SiP (e.g., using signals routed through the interposer), a higher bandwidth may be achieved between the HBM devices and the host device than in conventional systems. The high-bandwidth interface within the SiP device enables large amounts of data to move quickly between the host device (e.g., GPU/CPU) and HBM devices during operation, thereby allowing the SiP device to quickly complete computing operations once data is loaded into the HBM devices. SiP devices, in turn, are typically integrated with a package substrate (e.g., a PCB) adjacent to other electronics and/or other SiP devices within a packaged system.

Packaging processes employed when forming SiP devices and/or integrating the SiP devices with package substrates, however, can impose mechanical or other stresses upon—and/or can induce warping, die cracking, and/or or other issues in—the SiP devices and/or the package substrates. Additionally, packaging processes rely on compatibility between SiP devices and package substrates (e.g., alignment of bond pads for package interconnects). Accordingly, before packaging processes are employed and implemented in bulk (and/or before SiP devices are manufactured in bulk), integration bringup processes are used to study (e.g., characterize, test) whether SiP devices of a particular construction or design will be compatible with certain package substrates and/or packaging processes.

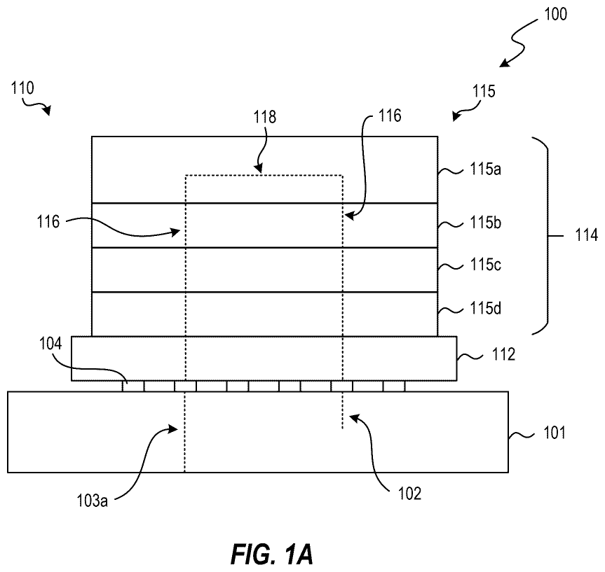

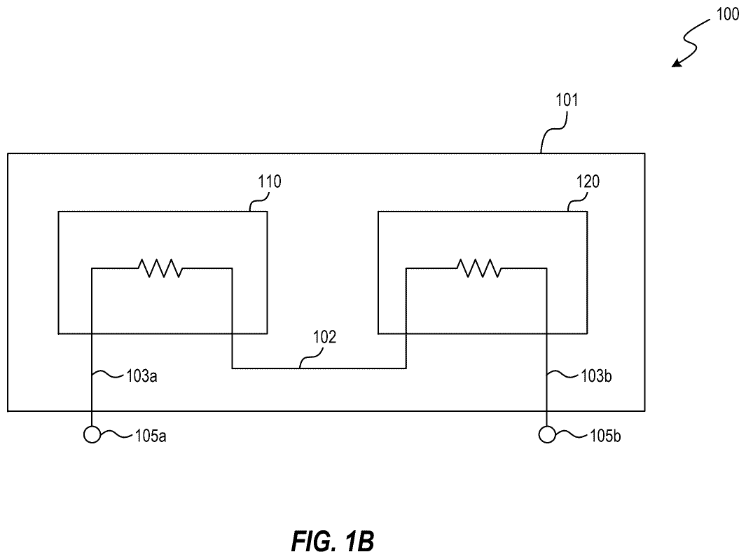

Typically, integration bringup processes for SiP devices use DCTVs (a) to simulate HBM devices of the SiP devices and (b) to test various connections between components of the SiP devices and/or between integrated package substrates and components of the SiP devices. For example, FIGS. 1A and 1B are a partially schematic cross-sectional view and a partially schematic top view, respectively, of an environment 100 that includes a first DCTV 110 and a second DCTV 120 (FIG. 1B) coupled to a substrate 101 (e.g., a silicon interposer, a dummy substrate, or another suitable substrate) via one or more interconnects 104 (FIG. 1A). Referring first to FIG. 1A, the first DCTV 110 is constructed with an architecture (e.g., shape, design, structure) that is similar to the architecture of a conventional HBM device. For example, the first DCTV 110 includes a base substrate 112 (e.g., an interface substrate) and a stack 114 of substrates 115 (identified individually in FIG. 1A as substrates 115a-115d) disposed on (e.g., carried by, coupled to, integrated with) the base substrate 112.

The first DCTV 110 further includes through substrate vias 116 (“TSVs 116”) that extend through the base substrate 112 and to an uppermost substrate 115a in the stack 114. As shown, the TSVs 116 are shorted together using a connection line 118 (e.g., a metallization layer in the uppermost substrate 115a). The TSVs 116 are also electrically coupled to route line 102 and route line 103a that extend throughout the substrate 101. As discussed in greater detail below, the route line 102 and the route line 103a can be components of a channel used to communicate signals through the first DCTV 110 using the TSVs 116 and the connection line 118. Although the first DCTV 110 is designed and manufactured to resemble an HBM device, the base substrate 112 and/or the substrates 115 of the first DCTV 110 do not include any other circuits or active components (e.g., any of the front-end-of-line (FEOL) and middle-of-line (MOL) layers forming memory circuits, physical layers (PHYs), memory controllers, and/or the like) that would be included in a live HBM device. As such, besides communicating signals along the TSVs 116 and across the corresponding connection lines 118, the first DCTV 110 does not imitate any of the operations of a live HBM device.

Referring now to FIG. 1B, the second DCTV 120 can be identical (or at least generally similar) to the first DCTV 110. For example, the second DCTV 120 can include (i) a base substrate coupled to the substrate 101, (ii) a stack of substrates disposed on the base substrate, and (iii) one or more strings of TSVs (e.g., each similar to the string of TSVs formed at least in part by the TSVs 116 and the connection line 118 shown in FIG. 1A). Alternatively, the second DCTV 120 can have an architecture that is generally similar to (e.g., resembles, mimics, simulates) the architecture of another component of a SiP device, such as a host device, a system-on-chip (SoC) device, and/or the like. Similar to the first DCTV 110, the second DCTV 120 does not include any of the circuits and/or active components (e.g., FEOL and/or MOL layers, active processors, and/or the like) that would be included in a live product aside from the one or more strings of TSVs for communicating signals throughout the second DCTV 120.

As shown in FIG. 1B, the second DCTV 120 is communicably coupled to the first DCTV 110 via the route line 102 in the substrate 101. The second DCTV 120 is also coupled to a route line 103b that extends throughout the substrate 101. Although not shown in FIGS. 1A and 1B, the substrate 101 can be integrated with a package substrate (e.g., a printed circuit board (PCB) or another suitable substrate) as part of a SiP integration bringup process. The package substrate can include access pins 105 (identified individually in FIG. 1B as first access pin 105a and a second access pin 105b). The first access pin 105a can be coupled to the route line 103a, and the second access pin 105b can be coupled to the route line 103b. The first and second access pins 105a and 105b can be coupled to a tester/external controller (not shown) and/or can be used to communicate signals through the substrate 101 (e.g., via one of the route lines 103a, 103b); across the first DCTV 110, the route line 102, and the second DCTV 120; and back through the substrate 101 (e.g., via the other of the route lines 103a and 103b).

As discussed above, the first DCTV 110 and the second DCTV 120 can be used as stand-ins for HBM devices and/or other components of a SIP during SiP integration bring-up processes (e.g., to simulate how HBM devices, other components of a SiP, the substrate 101, and/or a package substrate integrated with the substrate 101 would react were the same or similar packaging processes be used (i) to integrate the HBM devices/other components with the substrate 101 and/or (ii) to integrate the substrate 101 with the package substrate). More specifically, after integrating the first DCTV 110 and the second DCTV 120 with the substrate 101 and/or integrating the substrate 101 with a package substrate, the first DCTV 110 and the second DCTV 120 can be used to identify issues (e.g., TSV failures or other connection issues) that indicate such packaging processes would create reliability issues if employed to integrate (a) HBM devices and/or other components of the same or similar architecture as the first DCTV 110 and/or the second DCTV 120 with (b) the substrate 101 and/or a package substrate.

Use of such DCTVs, however, suffer from several shortcomings. First, to simulate a HBM device, SoC device, or another component, the first DCTV 110 and the second DCTV 120 must be specifically designed, fabricated, and assembled to resemble the HBM device, SoC device, or another component. In other words, use of DCTVs requires added design and manufacturing steps and costs directed to the DCTVs. Second, as discussed above, the first and second DCTVs 110, 120 do not include any of the circuits and/or active components that are included in the live products they simulate. As such, the first DCTV 110 and the second DCTV 120 have considerably different material compositions and mechanical properties than the live products they are intended to resemble. Therefore, the first DCTV 110, the second DCTV 120, the substrate 101, and/or a corresponding package substrate may exhibit different responses (e.g., different warpage, different cracking) during the SiP integration bringup processes than would otherwise occur using live products in place of the first DCTV 110 and/or the second DCTV 120. As a result, the first DCTV 110 and/or the second DCTV 120 may not provide a fully accurate characterization of how the first DCTV 110, the second DCTV 120, the substrate 101, and/or the package substrate would respond to particular packaging processes.

Third, the first DCTV 110 and the second DCTV 120 include only strings of TSVs for identifying communications issues; they do not include any other circuits and/or active components. Accordingly, a tester/external controller is limited to executing direct current (DC) connectivity tests (e.g., measuring resistance through the first DCTV 110, the communication channel 102, the second DCTV 120, and/or the route lines 103a, 103b) to assess connections between (a) the first DCTV 110 and the second DCTV 120, (b) the substrate 101 and a package substrate to which it is integrated, and/or (c) the package substrate and the first DCTV 110 and/or the second DCTV 120. Stated another way, the first DCTV 110 and the second DCTV 120 enable limited testing and therefore provide limited information useful for characterizing compatibility between (a) components of SiP devices and (b) package substrates and/or manufacturing processes. Purely by way of example, the first DCTV 110 and the second DCTV 120 do not allow integration bringup processes to include various alternative current (AC) measurements and/or operational characterizations.

To address these shortcomings, several embodiments of the present technology are related to proxy devices and associated SiP integration bringup processes that, in lieu of DCTVs, utilize test vehicles having circuits and other active components. In some embodiments, the test vehicles can be HBM devices. For example, the test vehicles can be or include HBM devices having at least a minimum basic functionality. As a specific example, the test vehicles can be or include HBM devices that have been identified as functional rejects (e.g., HBM devices that have been rejected during quality control or other testing from being implemented into customer products, but that have at least minimum basic functionality useful for conducting one or more tests included in SiP integration bringup processes of the present technology).

Associated SiP integration bringup processes of the present technology can include integrating (e.g., stacking, electrically coupling) multiple test vehicles with a substrate to form a proxy device, and/or integrating such a proxy device with a package substrate (e.g., a PCB) to communicably couple the test vehicles to the package substrate. Thereafter, the SiP integration bringup processes can include coupling the package substrate to an external testing device (e.g., a tester, an external controller) to place the external testing device in communication with the test vehicles, and using the external testing device to execute one or more tests useful for characterizing compatibility between the test vehicles, live devices simulated by the test vehicles, the substrate, SiP devices simulated by the proxy device, the package substrate, and/or packaging processes.

As discussed above, test vehicles of the present technology can include a variety of circuits and/or active components (e.g., FEOL and/or MOL circuits/components) formed therein. These circuits and/or active components of the test vehicles can be leveraged to provide greater testing functionality than is available with DCTVs. For example, test vehicles of the present technology can enable execution of various connectivity tests, such as AC connectivity tests (e.g., using multiple input signature registers (MISRs) of input/output circuits of the test vehicles, and/or using other AC communication signals) in addition to or in lieu of DC connectivity tests, to confirm integrity of communication circuits and other components within and/or between the test vehicles. As another example, test vehicles of the present technology can enable execution of other types of tests, such as tests that identify or characterize die cracks in the test vehicles and/or any other suitable tests. In other words, the test vehicles of the present technology can enable a greater variety of tests during SiP integration bringup processes than can be conducted using the first DCTV 110 and the second DCTV 120 discussed above with reference to FIGS. 1A and 1B. As such, test vehicles of the present technology are expected to enable a more extensive and/or accurate assessment of compatibility between the test vehicles (and the devices they are analogous to), the package substrate, and/or the packaging processes.

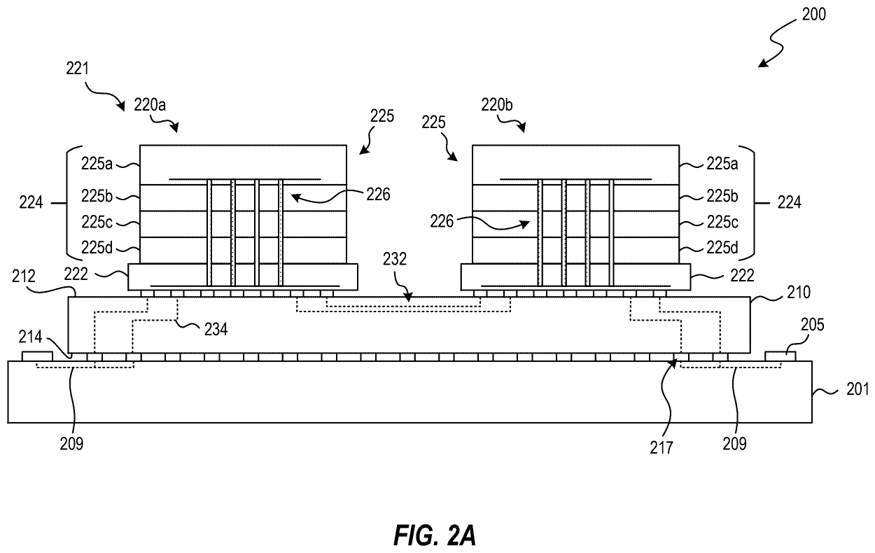

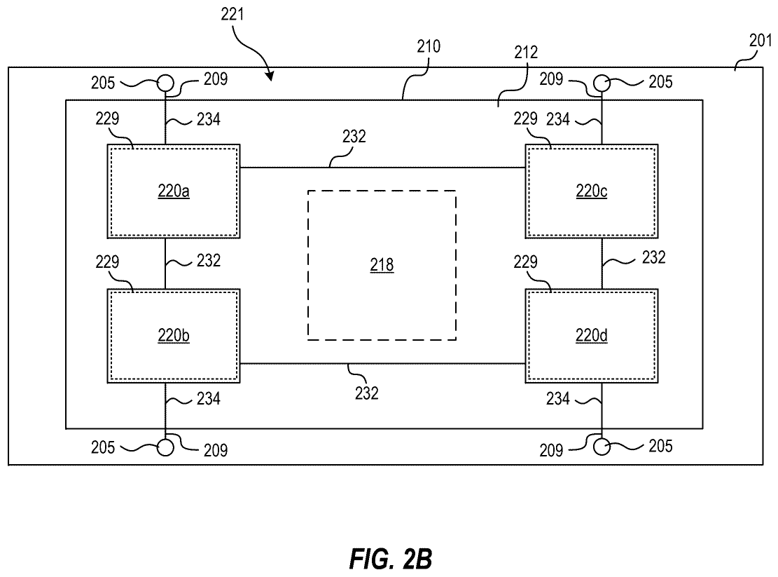

Further, test vehicles of several embodiments of the present technology can be designed and manufactured using identical (or at least generally similar) processes as those used to design/manufacture HBM devices or other devices simulated by the test vehicles. As a result, especially in embodiments in which tests vehicles are or include HBM devices with at least minimum basic functionality, test vehicles of the present technology may not require independent design and/or fabrication processes, thereby obviating many or all of the additional design/manufacturing steps and costs associated with use of DCTVs. As another result, because the test vehicles include identical (or at least generally similar) mechanical properties, compositions, and/or other characteristics as the devices that they simulate, the test vehicles of the present technology are expected to provide a more accurate (e.g., true) indication of how the simulated devices will react (e.g., warp, crack, etc.) when integrated with a substrate to form a proxy device and/or when the proxy device is integrated with a package substrate. Thus, test vehicles of the present technology are expected to provide a better assessment of compatibility between the simulated devices, corresponding SiP devices, package substrates, and/or packaging processes. Additional details on test vehicles and associated SiP integration bringup processes of the present technology are described below with reference to FIGS. 2A-4.

FIG. 2A is a partially schematic cross-sectional view of an environment 200 configured in accordance with various embodiments of the present technology. As shown, the environment 200 includes a proxy device 221 integrated with a package substrate 201 (e.g., a PCB or another suitable substrate). The proxy device 221 (sometimes also referred to herein as a “SiP proxy device,” a “SiP device,” a “device,” and/or the like) includes a first test vehicle 220a and a second test vehicle 220b that are each integrated with a base substrate 210 (e.g., a silicon interposer, a substrate of organic material, a substrate of inorganic material, and/or any other suitable material), such as at an upper surface 212 of the base substrate 210. In the illustrated embodiment, each of the first test vehicle 220a and the second test vehicle 220b includes a base die 222 (e.g., an interface die or other suitable substrate), a stack 224 of memory dies 225 (e.g., DRAM dies and/or another suitable type of memory die) carried by the base die 222, and TSVs 226 extending between the base die 222 and each of the memory dies 225 in the stack 224. The memory dies 225 of each stack 224 illustrated in FIG. 2A are identified individually as memory dies 225a-225d.

In some embodiments, the first test vehicle 220a and/or the second test vehicle 220b can include circuits and/or active components (e.g., FEOL and/or MOL layers forming memory circuits/components, physical layers (PHYs), and/or various other suitable circuits/components) in the base dies 222 and/or in one or more of the memory dies 225 of the stacks 224. For example, the first test vehicle 220a and/or the second test vehicle 220b can resemble HBM devices. As a specific example, as discussed in greater detail below, the first test vehicle 220a and/or the second test vehicle 220b can be or include HBM devices with minimum basic functionality (e.g., HBM devices that have been identified as functional rejects and/or that have been rejected during quality control or other testing from being implemented into customer products, but that have at least minimum basic functionality useful for conducting one or more tests included in SiP integration bringup processes of the present technology). Continuing with this example, the first test vehicle 220a and/or the second test vehicle 220b can therefore include compositions, mechanical properties, and/or other characteristics identical (or at least generally similar) to a fully functioning HBM device. Thus, in such an example, the first test vehicle 220 and/or the second test vehicle 220b are expected to provide a better (e.g., more true, more accurate) representation of the fully functioning HBM device than a DCTV.

As further illustrated in FIG. 2A, the base substrate 210 can include one or more communication channels 232 and one or more interconnects 234. The communication channels 232 communicably couple the first test vehicle 220a to the second test vehicle 220b. The interconnects 234 couple the first test vehicle 220a and the second test vehicle 220b to external interconnects 217 (e.g., solder structures, metal pads, and/or any other suitable structure) at a lower surface 214 of the base substrate 210. In turn, the external interconnects 217 can be coupled to one or more access pins 205 of the package substrate 201, such as via route lines or interconnects 209 in the package substrate 201. As such, the first test vehicle 220a and the second test vehicle 220b can each be communicably coupled to at least one of the access pins 205. In some embodiments, the access pins 205 can be direct access pins or direct access external balls of or on the package substrate 201. As discussed in greater detail below, the access pins 205 can be coupled to an external testing device (e.g., a tester, an external controller). Therefore, the external testing device can communicate with (e.g., access, control, send signals to, receive signals from) the first test vehicle 220a and/or the second test vehicle 220b via at least one of the access pins 205 to, for example, implement one or more tests (e.g., DC signal tests, AC signal tests, die crack tests, and/or the like) during a SiP integration bringup process.

Purely by way of example, the first test vehicle 220a can be instructed (e.g., by an external testing device coupled to two or more of the access pins 205) to communicate a DC signal to the second test vehicle 220b via the communication channels 232. The DC signal can then be read out from the second test vehicle 220b (e.g., by the external testing device and/or via one of the access pins 205) to determine whether the correct signal was received (and/or whether any signal was received). If the correct signal was not received or if no signal was received, this can indicate that there is a bad connection within the first test vehicle 220a, within the second test vehicle 220b, within the communication channels 232, and/or within the interconnects 234, 217, and/or 209 between the first and second test vehicles 220a, 220b and the access pins 205. The bad connection, in turn, indicates a lack of compatibility between the first test vehicle 220a, the second test vehicle 220b, the base substrate 210, the proxy device 221, the package substrate 201 and/or the packaging process(es) used to integrate these components with one another.

FIG. 2B is a partially schematic top view of the environment 200 of FIG. 2A. As shown, the proxy device 221 can include test vehicles 220 in addition to the first test vehicle 220a and the second test vehicle 220b described above with reference to FIG. 2A. More specifically, in the illustrated embodiment, the proxy device 221 includes a third test vehicle 220c and a fourth test vehicle 220d. Although shown with four test vehicles 220a-220d in the illustrated embodiment, the proxy device 221 can include a different number of test vehicles 220 (e.g., one, two, three, or more than four test vehicles) in other embodiments of the present technology.

In the illustrated embodiment, the tests vehicles 220a-220d are positioned around a host-connect region 218 of the base substrate 210. The host-connect region 218 (sometimes also referred to herein as a “central portion,” a “host-connecting portion,” and/or the like) can be integrated with a host device (e.g., a graphics processing unit, a computer processing unit, and/or any other suitable device) or with a test vehicle/stand-in device that resembles the host device. The host device (or corresponding test vehicle), however, is not necessary for executing SiP integration bringup processes. Accordingly, the host device/corresponding test vehicle can be omitted in some embodiments to save time and/or costs associated with producing the host device/corresponding test vehicle and/or with integrating the host device/corresponding test vehicle with the base substrate 210. In some embodiments, however, the proxy device 221 can include a host device or a test vehicle/stand-in device that simulates/resembles a host device. In such embodiments, the host device/corresponding test vehicle can be integrated with the host-connect region 218 of the base substrate 210. In some such embodiments that utilize a test vehicle to resemble/simulate the host device, the test vehicle can be or include a host device with minimum basic functionality, such as a functional reject or a host device otherwise rejected (e.g., during quality control and/or other testing processes) from being implemented into a customer device. Including the host device (or a corresponding stand-in device) may provide a better (e.g., more true, more accurate) representation of warpage and/or other responses of various components of a SiP device resembled by the proxy device 221 and/or of the package substrate 201. In other words, including the host device or a corresponding stand-in device may provide a better assessment or characterization of compatibility between various components of the proxy device 221 (and/or of components of a SiP device simulated by the proxy device 221), the package substrate 201, and/or packaging processes used to integrate these components with one another.

As further illustrated in FIG. 2B, similar to the first test vehicle 220a and the second test vehicle 220b described above with reference to FIG. 2A, the third test vehicle 220c and the fourth test vehicle 220a can be communicably coupled to one another via native communication channels 232 in the base substrate 210. Additionally, or alternatively, the third test vehicle 220c can be communicably coupled to the first test vehicle 220a via native communication channels 232 in the base substrate 210, and/or the fourth test vehicle 220d can be communicably coupled to the second test vehicle 220b via native communication channels 232 in the base substrate 210. Continuing with the illustrated example, the first and second test vehicles 220a, 220b can form a first pair; the third and fourth test vehicles 220c, 220d can form a second pair; the first and third test vehicles 220a, 220c can form a third pair; and the second and fourth test vehicles 220b, 220d can form a fourth pair.

Further, each of the test vehicles 220a-220d can be coupled to one of the access pins 205 on the package substrate 201. As a result, each of the pairs (or any subset thereof) can be used (e.g., by an external testing device coupled to one or more of the access pins 205) to implement various tests, such as during a SiP integration bringup process. In some embodiments, executing a SiP integration bringup process includes executing duplicative tests with the pairs (e.g., multiple DC signal tests to evaluate how many bad connections, if any, exist in the environment 200 and/or to attempt to identify where in the environment 200 a connectivity issue is located). As a specific example, a first DC connectivity test can be performed using the first test vehicle 220a and the second test vehicle 220b. If a connectivity issue is identified during the first test, a second DC connectivity test can be performed using the first test vehicle 220a and the third test vehicle 220c to, for example, determine whether the connectivity issue is likely located within the first test vehicle 220a or another portion of the communication paths common to both the first and second tests. Additional test can be conducted (as needed) to determine a location of the connectivity issue. As another example, executing a SiP integration bringup process can include simultaneously implementing multiple tests using the pairs (e.g., using the first pair to implement a first test while using the second pair to implement a second test).

As discussed above, inclusion of a host device integrated with the host-connect region 218 of the base substrate 210 is optional. As a result, in some embodiments, the communication channels 232 in the base substrate 210 can avoid or not be routed to/through the host-connect region 218. Said another way, executing a SiP integration bringup process may include performing one or more tests using the test vehicles 220a-220d but not the host-connect region 218 or a host device/stand-in device integrated with the host-connect region 218. Thus, in some embodiments, the base substrate 210 can omit communication channels that would otherwise communicably couple the test vehicles 220 to the host device. Alternatively, in some embodiments, the base substrate 210 can include communication channels (not shown) between one or more of the test vehicles 220 and the host-connect region 218, thereby allowing a host device/stand-in device to be included in various tests (e.g., MISR reads to confirm an integrity of cache memories formed in the host device) executed as part of a SiP integration bringup process. In still other embodiments, the host-connect region 218 can be omitted.

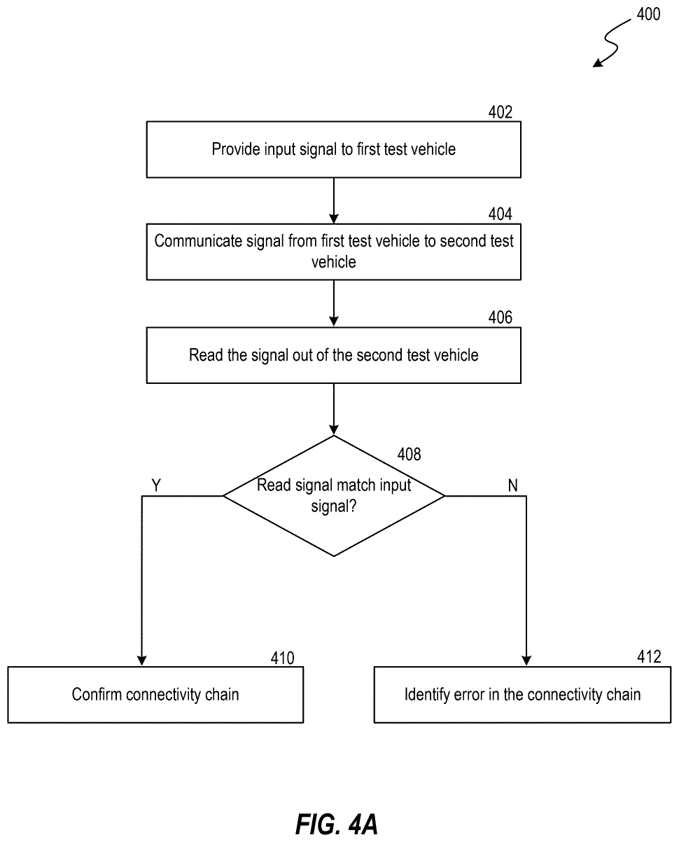

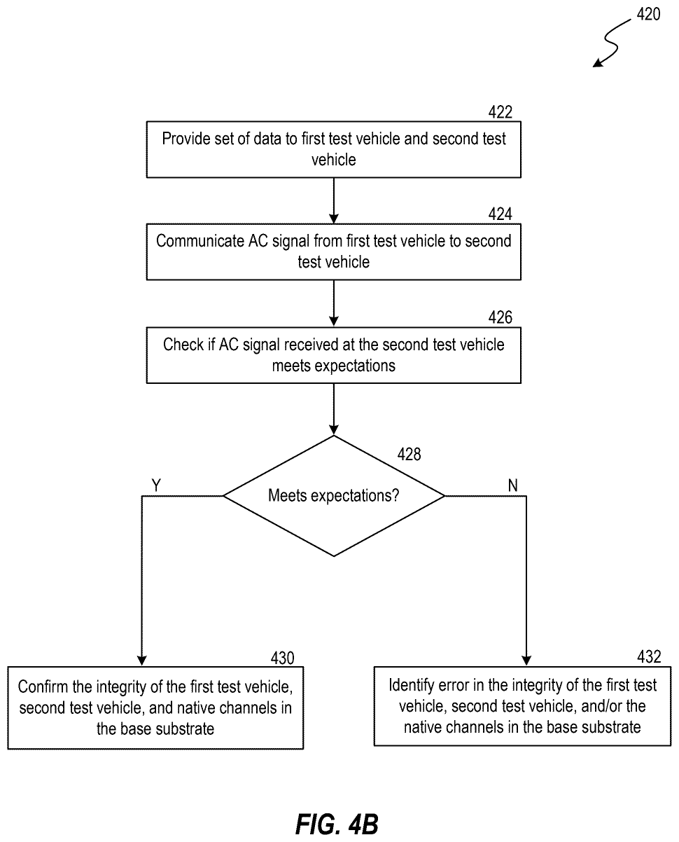

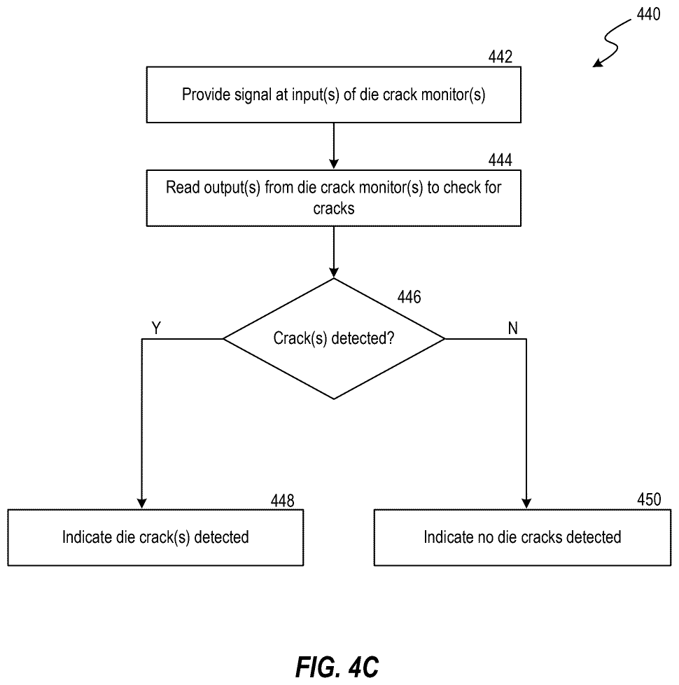

As further illustrated in the embodiment of FIG. 2B, each of the test vehicles 220a-220d can include one or more die crack monitors 229. In some embodiments, the die crack monitors 229 can be formed in the base die 222 and/or in one or more of the memory dies 225 of the test vehicles 220a-220d. The die crack monitors 229 (sometimes referred to as “die crack sensors”) can include a circuit that traces or extends about a perimeter of the corresponding die. The circuit (e.g., a metal route line and/or other suitable structure) of each die crack monitor 229 can include an input and an output. When a signal (e.g., a DC signal) is loaded onto the input, the signal can be read at the output to confirm that the circuit is intact. A crack in the corresponding die, however, may disrupt or break the circuit, resulting in losses in the signal and/or in breaking of the circuit altogether. Further, because the circuit traces or extends about a perimeter of the corresponding die, the die crack monitors 229 can detect a crack resulting from mechanical stresses/impacts before the crack damages other circuits in the corresponding die (e.g., transistors in the DRAM dies). For example, the die crack monitors 229 can detect mechanical damage that has not yet undermined the integrity of the dies in the HBM devices, but could propagate over time and reduce the lifetime of the resulting packaged device. A process of checking the die crack monitors 229 is discussed in greater detail below with reference to FIG. 4C. In some embodiments, one or more of the test vehicles 220a-220d include a plurality of the die crack monitors 229 (e.g., one on each die therein). In some embodiments, one or more of the test vehicles 220a-220d include a single one of the die crack monitors 229 (e.g., one on an uppermost die 215 of the corresponding stack 224). Further, in some embodiments, only a subset of the test vehicles 220a-220d includes one or more die crack monitors 229.

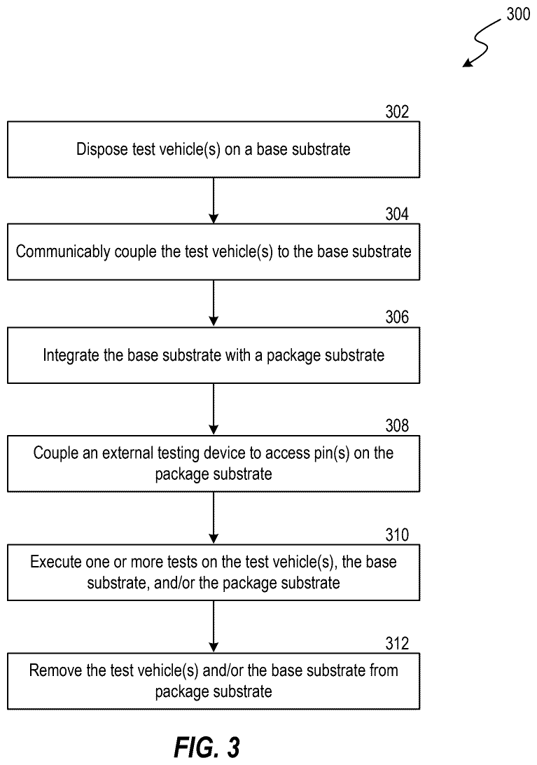

FIG. 3 is a flow diagram illustrating a process 300 for testing compatibility of semiconductor components in accordance with various embodiments of the present technology. More specifically, the process 300 can be implemented as part of a SiP integration bringup process to test compatibility of SiP devices with a package substrate (e.g., a PCB and/or the like) and/or one or more packaging processes. The process 300 is illustrated as a set of steps or blocks 302, 304, 306, 308, 310, and 312. All or a subset of one or more of these blocks 302, 304, 306, 308, 310, and 312 can be executed in accordance with the discussion above and/or with the discussion of FIGS. 4A-4C below. Indeed, several of the blocks 302, 304, 306, 308, 310, and 312 of the process 300 are described below with reference to the environment 200 of FIGS. 2A and 2B.

The process 300 begins at block 302 by dispose one or more test vehicles on a base substrate. In some embodiments, disposing the one or more test vehicles on the base substrate can include disposing the one or more test vehicles on the base substrate as part of forming a proxy device (e.g., a device that resembles another device, such as a SiP device incorporating one or more HBM devices and/or a host device). In these and other embodiments, disposing the one or more test vehicles on the base substrate can include disposing a plurality (e.g., two or more) test vehicles on the base substrate. In these and still other embodiments, each test vehicle can include circuits and/or other active components. For example, as discussed above, the test vehicle(s) can be or include HBM devices having minimum basic functionality for performing tests that facilitate characterizing compatibility of various semiconductor devices with one another and/or with various packaging processes. Continuing with this example, the test vehicles can be or include HBM devices (a) that have been identified as functional rejects, such as during a quality check or other testing process, and/or (b) that have been collected specifically for use in the process 300. In other embodiments, the process 300 at block 302 includes identify HBM devices that are functional rejects for use as test vehicles. Referring to FIG. 2A as a specific example of block 302, block 302 of the process 300 can include disposing the first and second test vehicles 220a, 220b on the base substrate 210.

At block 304, the process 300 continues by communicably coupling the test vehicle(s) to the base substrate. In some embodiments, communicably coupling the test vehicle(s) to the base substrate includes communicably coupling the test vehicle(s) to the base substrate using metal posts, solder structures, metal-metal contacts, and/or any other suitable interconnect structures. For example, communicably coupling the test vehicle(s) to the base substrate can include communicably coupling the test vehicle(s) to bond pads at an upper surface of the base substrate. Additionally, or alternatively, communicatively coupling the test vehicle(s) to the base substrate can include communicably coupling the test vehicle(s) to one or more communication channels and/or interconnects in the base substrate, such as the communication channels 232 and/or the interconnects 234 in the base substrate 210 of FIGS. 2A and 2B. The communication channels, in turn, can communicably couple two or more test vehicles together (e.g., allowing the pairs to be used for various testing processes). As discussed in greater detail below, the interconnects can communicably couple corresponding test vehicles to access pins of a package substrate.

At block 306, the process 300 continues by integrating the base substrate device with a package substrate. Integrating the base substrate with the package substrate can include integrating the proxy device (e.g., including the base substrate and one or more test vehicles disposed thereon) with the package substrate. Additionally, or alternatively, integrating the base substrate with the package substrate can include integrating the base substrate with the package substrate using metal posts, solder structures, metal-metal contacts, and/or any other suitable interconnect structures, such as bond pads and/or external interconnects similar to the external interconnects 217 of FIG. 2A. Integrating the base substrate with the package substrate can therefore include packaging the base substrate with the package substrate according to a packaging process being evaluated as part of a SiP integration bringup process. Assuming the base substrate, the proxy device, and/or the package substrate are compatible with one another and with the packaging process, integrating the base substrate with the package substrate can include coupling the test vehicle(s) disposed on the base substrate to two or more access pins of the package substrate (e.g., the access pins 205 of the package substrate 201 of FIG. 2A), such as via interconnects in the package substrate, interconnects in the base substrate, and/or external interconnects coupling the interconnects in the package substrate to the interconnects in the base substrate.

At block 308, the process 300 continues by coupling an external testing device to one or more access pins of the package substrate. In some embodiments, coupling the external testing device to one or more access pins of the package substrate includes coupling the external testing device to two or more access pins of the package substrate. Additionally, or alternatively, assuming the base substrate, the proxy device, and/or the package substrate are compatible with one another and with the packaging process, the external testing device (e.g., a tester or an external controller) can be coupled to one or more of the test vehicles disposed on the base substrate to, for example, send signals to (and/or receive signals from) the one or more test vehicles.

At block 310, the process 300 continues by executing one or more tests (sometimes also referred to herein as “integration bringup tests”) on the test vehicle(s), the base substrate, and/or the package substrate using the external testing device. In some embodiments, executing the one or more tests includes measuring a resistance (e.g., using DC signals) along any suitable connectivity chain in the test vehicle(s), the base substrate, and/or in the package substrate. As a specific example with reference to FIG. 2B, executing the one or more tests can include measuring a resistance along a first connectivity chain including the first test vehicle 220a, the communication channel 232, and the second test vehicle 220b; a second connectivity chain including the third test vehicle 220c, the communication channel 232, and the fourth test vehicle 220d; and so on). Additionally, or alternatively, executing the one or more tests can include executing one or more DC connectivity tests to confirm there are no breaks in the connectivity chains, executing one or more tests using AC signals (e.g., using a MISR value to confirm there is no loss of integrity in one or more of the test vehicles), executing one or more die crack and/or die edge monitoring tests (e.g., to detect the presence, extent, and/or location of cracking within the test vehicles, the base substrate, and/or the package substrate), and/or executing one or more other suitable tests. Additional details on several of these tests are provided below with reference to FIGS. 4A-4C.

Tests executed at block 310 of the process 300 can help assess connections within various connectivity strings or chains, integrity of circuits within the test vehicles and/or integrity of various communication channels, warpage and other mechanical stresses, and/or the like. In other words, tests executed at block 310 of the process 300 can facilitate evaluating/characterizing whether the test vehicle(s) and/or the base substrate is/are compatible with the package substrate and/or the packaging process used to integrate the proxy device (including the test vehicle(s) and the base substrate) with the package substrate. Further, because each test vehicle is constructed as a direct analog to a live device (e.g., a fully functioning HBM device), the tests are expected to provide a direct example/representation of the compatibility between (a) such live devices and corresponding SiP devices and (b) the package substrate and/or the associated packaging process-albeit without a host device, with communication channels in the base substrate extending directly between test vehicles, and/or without communication channels extending between the test vehicle(s) and a host-connect region-. Said another way, use of test vehicles configured in accordance with various embodiments of the present technology in SiP integration bringup processes is expected to provide a better (e.g., more true, more accurate) representation of the compatibility of devices simulated by the test vehicles in comparison to use of DCTVs in integration bringup processes.

At block 312, the process 300 continues by removing the test vehicle(s) and/or the base substrate from the package substrate. Removing the test vehicle(s) and/or the base substrate from the package substrate can include uncoupling and/or physically separating the test vehicle(s) from the base substrate and/or the base substrate from the package substrate. In some embodiments, the package substrate can thereafter be re-used in additional SiP integration bringup processes (e.g., repeated processes to confirm the results) and/or coupled to a SiP device (e.g., to form a packaged product). Additionally, or alternatively, the test vehicle(s) and/or the base substrate can then be integrated with one or more additional package substrates (e.g., repeated processes to confirm the results with respect to the test vehicle(s) and/or the base substrate, and/or to confirm the additional package substrates are compatible with the test vehicle(s) and/or the base substrate).

Although the blocks 302, 304, 306, 308, 310, and 312 of the process 300 are discussed and illustrated in a particular order, the process 300 illustrated in FIG. 3 is not so limited. In other embodiments, the process 300 can be performed in a different order. In these and other embodiments, any of the blocks 302, 304, 306, 308, 310, and 312 of the process 300 can be performed before, during, and/or after any of the other blocks 302, 304, 306, 308, 310, and 312 of the process 300. For example, all or a subset of the block 302 can be executed at a same timing as all or a subset of block 304 (sometimes referred to collectively as integrating the test vehicle(s) with the base substrate). As another example, all or a subset of blocks 306 and/or 308 can be performed before executing all or a subset of blocks 302 and/or 304. Moreover, a person of ordinary skill in the relevant art will recognize that the illustrated process 300 can be altered and still remain within these and other embodiments of the present technology. For example, one or more blocks 302, 304, 306, 308, 310, and 312 of the process 300 illustrated in FIG. 3 can be omitted and/or repeated in some embodiments. As a specific example, all or a subset of block 312 can be omitted in some embodiments such that the process 300 completes after block 310. In some such embodiments, the test vehicle(s) can be removed from the base substrate while the base substrate is left on the package substrate. Additionally, or alternatively, the test vehicle(s) can be replaced with one or more live devices (e.g., to form a packaged product), such as the live device(s) the test vehicle(s) are intended to simulate. In other embodiments, the package substrate, the base substrate, and/or the test vehicles can be disposed after the process 300 terminates at block 310.

FIG. 4A is a flow diagram illustrating a DC signal test process 400 in accordance with various embodiments of the present technology. The process 400 can be an example of a test implemented at block 310 of the process 300 described above with reference to FIG. 3 as part of a SiP integration bringup process. In some embodiments, the process 400 can be informed by prior testing processes that affect or clarify the results of the process 400. Purely by way of example, when multiple tests are performed on a proxy device, the process 400 can implement the DC signal test using only communication chains that were previously found to be intact. The process 400 of FIG. 4A is illustrated as a set of steps or blocks 402, 404, 406, 408, 410, and 412. All or a subset of one or more of the blocks 402, 404, 406, 408, 410, and 412 can be executed in accordance with the discussion above and/or with the discussion of FIGS. 4B and 4C below.

The process 400 begins at block 402 by providing an input signal (e.g., a first signal) to a first test vehicle of a proxy device. The proxy device can be integrated with a package substrate. In some embodiments, providing the input signal to the first test vehicle can include providing (e.g., using an external testing device) the input signal to an access pin of the package substrate that is coupled to the first test vehicle via the package substrate and a base substrate of the proxy device. In these and other embodiments, the first test vehicle can be a test vehicle of a pair of test vehicles that are communicably coupled to one another via communication channels in the base substrate. The input signal (sometimes referred to as a “first signal,” an “input DC signal,” and/or the like) can be a DC signal having a value that can be communicated to the first test vehicle.

At block 404, the process 400 continues by communicating a signal from the first test vehicle to a second test vehicle of the proxy device. The communicated signal can be based at least in part on the input signal provided to the first test vehicle at block 402. Communicating the signal to the second test vehicle can include instructing the first test vehicle to communicate the signal to the second test vehicle and/or communicating the signal in response to such instructions. In some embodiments, instructing the first test vehicle can include instructing the first test vehicle using an external testing device. In response to the instructions, the first test vehicle (sometimes referred to as a “transceiver test vehicle”) can relay the signal to the second test vehicle, such as through a communication channel in the base substrate of the proxy device.

At block 406, the process 400 continues by reading a signal out of the second test vehicle (sometimes referred to as a “receiver test vehicle”). The signal read out of the second test vehicle can be based at least in part on (a) the signal communicated to the second test vehicle from the first test vehicle at block 404 and/or (b) the input signal provided to the first test vehicle at block 402. Reading the signal out of the second test vehicle can include reading the signal using an external testing device, and/or reading the signal through the base substrate of the proxy device and out of the package substrate via an access pin of the package substrate. As discussed in greater detail below, the read can allow the external testing device to confirm whether the signal (sometimes referred to as a “second signal,” an “output signal,” an “output DC signal,” and/or the like) read from the second test vehicle is equal to the input signal provided to the first test vehicle at block 402, which can indicate that a connectivity string/chain extending from a first access pin, through the package substrate, through the base substrate, through the first test vehicle, across the communication channels coupling the first test vehicle to the second test vehicle, through the second test vehicle, through the base substrate, through the package substrate, and to a second access pin is intact.

At decision block 408, the process 400 continues by determining if the signal read from the second test vehicle at block 406 matches the input signal provided to the first test vehicle at block 402. In the event that the signals are equal or within acceptable margins (block 408: Yes), the process 400 continues to block 410 to confirm a status of the corresponding connectivity string/chain as intact. As a result, the DC signal test, when executed as part of a SiP integration bringup process, can help to verify that the proxy device (including the first and second test vehicles and the base substrate) and/or a SiP device simulated by the proxy device properly integrate(s) with the package substrate using the associated packaging processes without unacceptable damage to the tested connectivity string/chain, suggesting that the proxy device (e.g., the test vehicle(s) and/or the base substrate included therein) and/or a SiP device simulated by the proxy device is/are compatible with the package substrate and the associated packaging processes. On the other hand, in the event that the received signal is not equal to the input signal (block 408: No), the process 400 continues to block 412 to identify an error or issue in the connectivity string/chain. As a result, the DC signal test, when executed as part of a SiP integration bringup process, can help to verify that the proxy device and/or a SiP device simulated by the proxy device does/do not properly integrate with the package substrate using the associated packaging processes and/or that at least a portion of the tested connectivity string/chain has been disrupted (e.g., damaged, compromised), thereby suggesting that the proxy device (e.g., the test vehicle(s) and/or the base substrate included therein) and/or a SiP device simulated by the proxy device is/are not compatible with the package substrate and/or the associated packaging processes.

As discussed above, the proxy device can include a plurality of test vehicles. The plurality of test vehicles can be arranged and/or coupled to one another in pairs. In some embodiments, the process 400 can be repeated for all or a subset of such pairs. The repetition, in turn, can help identify the location of a connectivity issue, as discussed above with reference to FIG. 2B. Additionally, or alternatively, the repetition can provide a more complete evaluation of the compatibility between the proxy device and the package substrate and/or the associated packaging processes (e.g., thereby quantifying post-mechanical stresses along the communication channels). In some cases, for example, three of the four pairs of HBM devices discussed above with reference to FIG. 2B can have functional communication chains suggesting a minor error in the packaging process. In some embodiments, a SiP integration bringup process can include an acceptable level of errors/issues such that, for example, three of four pairs having functional communication chains is acceptable but one of four is not. Additionally, or alternatively, the pairs with functional communication chains can be subjected to additional tests (e.g., the AC signal test discussed in more detail below with reference to FIG. 4B) while the pairs with non-functional communication chains can be left out of the additional tests to, for example, save time.

Although the blocks 402, 404, 406, 408, 410, and 412 of the process 400 are discussed and illustrated in a particular order, the process 400 illustrated in FIG. 4A is not so limited. In other embodiments, the process 400 can be performed in a different order. In these and other embodiments, any of the blocks 402, 404, 406, 408, 410, and 412 of the process 400 can be performed before, during, and/or after any of the other blocks 402, 404, 406, 408, 410, and 412 of the process 400. Moreover, a person of ordinary skill in the relevant art will recognize that the illustrated process 400 can be altered and still remain within these and other embodiments of the present technology. For example, one or more blocks 402, 404, 406, 408, 410, and 412 of the process 400 illustrated in FIG. 4A can be omitted and/or repeated in some embodiments. As a specific example, block 404 can be omitted, such as in embodiments in which an input signal is provided to a first test vehicle and then is subsequently read from the first test vehicle (e.g., to test communications paths internal to the first test vehicle and/or communication paths extending between the first test vehicle and one or more access pins of the package substrate).

FIG. 4B is a flow diagram illustrating an AC signal test process 420 in accordance with various embodiments of the present technology. The process 420 can be an example of a test implemented at block 310 of the process 300 described above with reference to FIG. 3 as part of a SiP integration bringup process. In some embodiments, the process 420 can be informed by prior testing processes that affect or clarify the results of the process 420. Purely by way of example, when multiple tests are performed on a proxy device, the process 420 can implement the AC signal test on test vehicles and/or pairs of test vehicles previously identified as functional or as properly coupled to (i) each other via the base substrate and/or (ii) the package substrate. The process 420 of FIG. 4B is illustrated as a set of steps or blocks 422, 424, 426, 428, 430, and 432. All or a subset of one or more of the blocks 422, 424, 426, 428, 430, and 432 can be executed in accordance with the discussion above and/or with the discussion of FIG. 4C below.

The process 420 begins at block 422 by providing a set of data to a first test vehicle and a second test vehicle of a pair of test vehicles. In some embodiments, the set of data can be a set of values communicated via AC signals. In some embodiments, the set of data can be a dummy set of data that can be used to calculate a MISR value at an end of flash memory cells in the first and second test vehicles. The set of values can be communicated to the first and second test vehicles using an external testing device and/or via the package substrate and/or a base substrate of a proxy device including the first and second test vehicles.

At block 424, the process 420 continues by communicating an AC signal from the first test vehicle to the second test vehicle. The AC signal can be based at least in part on the set of data provided to the first test vehicle at block 422. For example, the AC signal can communicate a portion (or all) of the set of data from the first test vehicle to the second test vehicle, such as using native channels in the base substrate that couple the first test vehicle to the second test vehicle. In some embodiments, the AC signal communicates a MISR value calculated from the set of data. In these and other embodiments, communicating the AC signal can include instructing the first test vehicle to send an AC signal to the second test vehicle. For example, an external testing device coupled to the first test vehicle via an access pin of the package substrate can be used to instruct the first test vehicle to send the AC signal.

At block 426, the process 420 continues by checking whether the AC signal received at the second test vehicle meets expectations. Checking whether the AC signal received at the second test vehicle meets expectations can include checking the AC signal using the second test vehicle. For example, when the first test vehicle communicates the AC signal to the second test vehicle, the second test vehicle can check whether the data received in the AC signal matches all or a subset of the set of data received and stored on the second test vehicle at block 422. In embodiments in which the AC signal communicates a MISR value calculated at the first test vehicle based at least in part on the set of data provided to the first test vehicle at block 422, the second HBM device can calculate a second MISR value based at least in part on the set of data provided to the second test vehicle at block 422, and can check whether the received MISR value matches the calculated MISR value.

At decision block 428, the process 420 continues by determining if the AC signal received at the second test vehicle meets expectations. In the event that the received AC signal meets expectations (block 428: Yes), the process 420 continues to block 430 to confirm the integrity of the first and second test vehicles and the corresponding native channels in the base substrate. For example, when the received AC signal communicates a MISR value, the process 420 at block 430 can confirm that the flash cells in the first and second test vehicles are functioning properly (e.g., were not damaged by the packaging process) and/or that the native communication channel in the base substrate and coupling the first and second test vehicles is not causing errors in signals transmitted between the first and second test vehicles. Thus, the AC signal test, when executed as part of a SiP integration bringup process, can help to verify that the proxy device (e.g., the first and second test vehicles and corresponding native channels in the base substrate) and/or a SiP device simulated by the proxy device is/are not disrupted by packaging processes integrating the proxy device with a package substrate. Said another way, the confirmed integrity can suggest that the proxy device (e.g., the first and second test vehicles and/or the base substrate) and/or a SiP simulated by the proxy device is/are compatible with the package substrate and the associated packaging processes. On the other hand, in the event that the received AC signal does not meet expectations (block 428: No), the process 420 continues to block 432 to identify an error in the integrity of the first and second test vehicles and the corresponding native channels in the base substrate. Thus, the AC signal test, when executed as part of a SiP integration bringup process can help to verify that the proxy device (e.g., the first and second test vehicles and/or the native communication channel in the base substrate) and/or a SiP device simulated by the proxy device is/are disrupted by associated packaging process, thereby suggesting the proxy device (e.g., the first and second test vehicles and/or the base substrate) and/or a SiP device simulated by the proxy device is/are not compatible with the package substrate and/or the associated packaging processes.

As discussed above, the test vehicle can include a plurality of test vehicles. The plurality of test vehicles can be arranged and/or coupled to one another in pairs. In some embodiments, the process 420 can be repeated for all or a subset of pairs. The repetition, in turn, can help identify the location of an issue, as discussed above with reference to FIG. 2B. Purely by way of example, if each pair of the test vehicles 220a-220d illustrated in FIG. 2B that does not include the first test vehicle 220a (e.g., the pair including the third and fourth test vehicles 220c, 220d; the pair including the second and third test vehicles 220b, 220c; and/or the pair including the second and fourth test vehicles 220b, 220d) is tested using the process 420 and reaches block 430 while pairs including the first test vehicle 220a end at block 432, the process 420 can determine that the location of an error/degradation of integrity is in the first test vehicle 220a. Additionally, or alternatively, the repetition of executing the process 420 multiple times can provide a more complete evaluation of the compatibility between the proxy device and the package substrate and/or the associated packaging processes and/or an extent of damage to the integrity of the test vehicles. In some embodiments, the process 420 can have an acceptable level for the loss of integrity (e.g., degradation of a single test vehicle may be acceptable while degradation of two or more test vehicles is not).

Although the blocks 422, 424, 426, 428, 430, and 432 of the process 420 are discussed and illustrated in a particular order, the process 420 illustrated in FIG. 4B is not so limited. In other embodiments, the process 420 can be performed in a different order. In these and other embodiments, any of the blocks 422, 424, 426, 428, 430, and 432 of the process 420 can be performed before, during, and/or after any of the other blocks 422, 424, 426, 428, 430, and 432 of the process 420. Moreover, a person of ordinary skill in the relevant art will recognize that the illustrated process 420 can be altered and still remain within these and other embodiments of the present technology. For example, one or more blocks 422, 424, 426, 428, 430, and 432 of the process 420 illustrated in FIG. 4B can be omitted and/or repeated in some embodiments. As a specific example, block 424 can be omitted, such as in embodiments in which a set of data is provided to a first test vehicle and then is subsequently read from the first test vehicle (e.g., to test the integrity of the first test vehicle and/or communication paths extending between the first test vehicle and one or more access pins of the package substrate).

FIG. 4C is a flow diagram illustrating a die crack detection process 440 in accordance with various embodiments of the present technology. The process 440 can be an example of a test implemented at block 310 of the process 300 described above with reference to FIG. 3 as part of a SiP integration bringup process. In some embodiments, the process 440 can be informed by prior testing processes that affect or clarify the results of the process 440. Purely by way of example, a crack detection process similar to the process 440 of FIG. 4C can be implemented to check for cracks in test vehicles after the test vehicles are attached to a base substrate of a proxy device. Continuing with this example, the prior crack detection process can inform the process 440 of FIG. 4C such that the process 440 searches only for new cracks in the test vehicles that occurred as a result of integrating the proxy device with a package substrate. In another example, when a test vehicle is reused for multiple SiP integration bringup processes, the process 440 can search only for new cracks that resulted from or occurred during the most recent process (e.g., by discounting cracks formed during previous test(s)). The process 440 of FIG. 4C is illustrated as a set of steps or blocks 442, 444, 446, 448, and 450. All or a subset of one or more of the blocks 442, 444, 446, 448, and 450 can be executed in accordance with the discussion above.

The process 440 begins at block 442 by providing a signal (e.g., a power signal) to an input of one or more die crack monitor(s) (e.g., one or more of the die crack monitors 229 of FIG. 2B) in one or more of the test vehicles of a proxy device. In some embodiments, the process 440 provides the signal to the input(s) of the die crack monitor(s) of a single test vehicle of the proxy device. In these and other embodiments, the process 440 provides the signal to the input(s) of the die crack monitor(s) of all or a subset of the test vehicles of the proxy device (e.g., only those test vehicles otherwise identified as being compatible with the package substrate and/or associated packaging processes as indicated by the tests discussed above with reference to FIGS. 4A and 4B).

At block 444, the process 440 continues by reading an output from the die crack monitor(s) to check for cracks. When a portion of a die crack monitor has been disrupted by a crack (e.g., when a perimeter wire is damaged), a signal read at the output of the die crack monitor will likely not be generally equal to the signal provided to the input of that die crack monitor. In this case, the process 440 can determine that a crack has occurred in a corresponding die of the corresponding test vehicle. In contrast, when the signal read at the output of a die crack monitor is generally equal to the signal provided to the input of that die crack monitor, the process 440 can determine that no crack has occurred in a corresponding die of the corresponding test vehicle.

At decision block 446, the process 440 continues by determining if one or more cracks were detected using the signals received at the output(s) of the die crack monitor(s). In the event that the process 440 determines one or more cracks were detected (block 446: Yes), the process 440 proceeds to block 448 to indicate that one or more cracks were detected in a corresponding test vehicle. In some embodiments, the process 440 can quantify and/or report the number of cracks that were detected and/or can report the location of such cracks. In some embodiments, the process 440 can report a raw number of cracks detected. In some embodiments, the process 440 can quantify and/or report a total number of test vehicles in which cracks were detected (e.g., when six cracks are detected, the process 440 can report a number of test vehicles exhibiting cracks to provide context of whether the cracks all occurred in a small subset of the test vehicles or were spread out across a larger number of the test vehicles). The number of cracks and/or the number of affected test vehicles, in turn, can be used to assess whether the proxy device (e.g., the test vehicles and/or the base substrate) and/or a SiP device simulated by the proxy device is/are compatible with the package substrate and/or the associated packaging processes. For example, a SiP integration bringup process can specify some threshold number of cracks and/or some threshold number of affected test vehicles above which the proxy device and/or a SiP device simulated by the proxy device can be considered incompatible with the package substrate and/or the associated packaging processed. Accordingly, when a number of cracks detected and/or a number of affected test vehicles is below the threshold number(s), the process 440 can indicate at block 448 that cracks were detected but that the proxy device (e.g., the test vehicles and/or the base substrate) and/or a SiP device simulated by the proxy device is/are likely compatible with the package substrate and/or the associated packaging processes.

On the other hand, in the event that that the process 440 no cracks (or no new cracks) were detected (block 446: No), the process 440 continues to block 450 to indicate that no die cracks (or no new die cracks) were detected. Such an indication can suggest that mechanical, thermal, and other stresses placed upon the proxy device and/or the package substrate when integrating the proxy device with the package substrate did not damage the proxy device and/or the package substrate, thereby indicating that the proxy device (e.g., the test vehicles, the base substrate, and/or the live products simulated by the test vehicles) and/or a SiP device stimulated by the proxy device is/are likely compatible with the package substrate and/or the associated packaging processes.

### CONCLUSION

From the foregoing, it will be appreciated that specific embodiments of the technology have been described herein for purposes of illustration, but well-known structures and functions have not been shown or described in detail to avoid unnecessarily obscuring the description of the embodiments of the technology. To the extent any material incorporated herein by reference conflicts with the present disclosure, the present disclosure controls. Where the context permits, singular or plural terms may also include the plural or singular term, respectively. Moreover, unless the word “or” is expressly limited to mean only a single item exclusive from the other items in reference to a list of two or more items, then the use of “or” in such a list is to be interpreted as including (a) any single item in the list, (b) all of the items in the list, or (c) any combination of the items in the list. Furthermore, as used herein, the phrase “and/of” as in “A and/or B” refers to A alone, B alone, and both A and B. Additionally, the terms “comprising,” “including,” “having,” and “with” are used throughout to mean including at least the recited feature(s) such that any greater number of the same features and/or additional types of other features are not precluded. Further, the terms “approximately” and “about” are used herein to mean within at least within 10% of a given value or limit. Purely by way of example, an approximate ratio means within 10% of the given ratio.

Several implementations of the disclosed technology are described above in reference to the figures. The computing devices on which the described technology may be implemented can include one or more central processing units, memory, input devices (e.g., keyboard and pointing devices), output devices (e.g., display devices), storage devices (e.g., disk drives), and network devices (e.g., network interfaces). The memory and storage devices are computer-readable storage media that can store instructions that implement at least portions of the described technology. In addition, the data structures and message structures can be stored or transmitted via a data transmission medium, such as a signal on a communications link. Various communications links can be used, such as the Internet, a local area network, a wide area network, or a point-to-point dial-up connection. Thus, computer-readable media can comprise computer-readable storage media (e.g., “non-transitory” media) and computer-readable transmission media.

From the foregoing, it will also be appreciated that various modifications may be made without deviating from the disclosure or the technology. For example, one of ordinary skill in the art will understand that various components of the technology can be further divided into subcomponents, or that various components and functions of the technology may be combined and integrated. In addition, certain aspects of the technology described in the context of particular embodiments may also be combined or eliminated in other embodiments.

Furthermore, although advantages associated with certain embodiments of the technology have been described in the context of those embodiments, other embodiments may also exhibit such advantages, and not all embodiments need necessarily exhibit such advantages to fall within the scope of the technology. Accordingly, the disclosure and associated technology can encompass other embodiments not expressly shown or described herein.

We claim:

1. A method for testing compatibility of a system-in-package (SiP) device with a package substrate, the method comprising:
forming a device as a proxy for the SiP device, wherein forming the device includes integrating a first test vehicle and a second test vehicle with an interposer, wherein integrating the first and second test vehicles with the interposer includes coupling each of the first and second test vehicles to a communication channel formed in the interposer to communicably couple the first test vehicle to the second vehicle, wherein each of the first and second test vehicles includes a stack of substrates, and wherein at least one substrate in each stack includes front-end-of-line (FEOL) or middle-of-line (MOL) layers;
integrating the device with the package substrate, wherein integrating the device with the package substrate includes communicably coupling the first and second test vehicles to two or more access pins of the package substrate;
coupling an external testing device to the two or more access pins; and
executing, using the external testing device, one or more tests on the first and second test vehicles.

2. The method of claim 1, wherein executing the one or more tests includes:
providing, via at least one of the two or more access pins, a first value to the first test vehicle;
communicating, using the first test vehicle, a signal to the second test vehicle via the communication channel, wherein the signal is based at least in part on the first value;
reading, via an access pin of the two or more access pins, a second value from the second test vehicle, wherein the second value is based at least in part on the signal;
determining that the second value is equal to the first value; and
based at least in part on the determination, confirming integrity of a communication path extending from the package substrate, through the first test vehicle, through the communication channel, through the second test vehicle, and back to the package substrate.

3. The method of claim 1, wherein executing the one or more tests includes:
providing, via at least one of the two or more access pins, a first value to the first test vehicle;
communicating, using the first test vehicle, a signal to the second test vehicle via the communication channel, wherein the signal is based at least in part on the first value;
reading, via an access pin of the two or more access pins, a second value from the second test vehicle, wherein the second value is based at least in part on the signal;
determining that the second value is not equal to the first value; and
based at least in part on the determination, identifying an error in a communication path extending from the package substrate, through the first test vehicle, through the communication channel, through the second test vehicle, and back to the package substrate.

4. The method of claim 1, wherein executing the one or more tests includes:
providing, via at least one of the two or more access pins, a first set of data to the first test vehicle;
providing, via an access pin of the two or more access pins, the first set of data to the second test vehicle;
transmitting, using the first test vehicle, an alternating current (AC) signal to the second test vehicle via the communication channel, wherein the AC signal is based at least in part on the first set of data and communicates a second set of data;
determining, at the second test vehicle, that the second set of data is equivalent to the first set of data; and
based at least in part on the determination, confirming integrity of the first test vehicle, the communication channel, and the second test vehicle.

5. The method of claim 1, wherein executing the one or more tests includes:
providing, via at least one of the two or more access pins, a first set of data to the first test vehicle;
providing, via an access pin of the two or more access pins, the first set of data to the second test vehicle;
transmitting, using the first test vehicle, an alternating current (AC) signal to the second test vehicle via the communication channel, wherein the AC signal is based at least in part on the first set of data and communicates a second set of data;
determining, at the second test vehicle, that the second set of data is equivalent to the first set of data; and
based at least in part on the determination, identifying an error in the first test vehicle, the communication channel, or the second vehicle.

6. The method of claim 1, wherein executing the one or more tests includes checking, using a die crack sensor in the first test vehicle, for cracks in a substrate of the first test vehicle resulting from integration of the device with the package substrate.

7. The method of claim 1, wherein integrating the device with the package substrate includes integrating the device with the package substrate at a timing when a host device is not integrated with the interposer.

8. The method of claim 1, wherein:
the communication channel is a first communication channel;
forming the device further includes integrating a third test vehicle and a fourth test vehicle with the interposer, wherein integrating the third and fourth test vehicles with the interposer includes coupling each of the third and fourth test vehicles to a second communication channel formed in the interposer to communicably couple the third test vehicle to the fourth test vehicle; and
executing the one or more tests includes executing a first subset of the one or more tests on the first and second test vehicles and a second subset of the one or more tests on the third and fourth test vehicles.

9. The method of claim 8, wherein integrating the first and third test vehicles with the interposer further includes coupling each of the first and third test vehicles to a third communication channel formed in the interposer to communicably couple the first test vehicle to the third test vehicle.

10. A proxy device for use with system-in-package (SiP) integration bringup processes, the proxy device comprising:
a base substrate;
two or more test vehicles carried by the base substrate, wherein each of the two or more test vehicles includes a base die and a stack of memory dies carried by the base die, wherein the two or more test vehicles include a first test vehicle and a second test vehicle; and
a communication channel formed in the base substrate and communicatively coupling the first test vehicle to the second test vehicle.

11. The proxy device of claim 10, wherein:
the two or more test vehicles further include a third test vehicle;
the communication channel is a first communication channel; and
the proxy device further comprises a second communication channel formed in the base substrate and communicatively coupling the first test vehicle to the third test vehicle.

12. The proxy device of claim 10, wherein the proxy device lacks a host device coupled to any of the two or more test vehicles.

13. The proxy device of claim 10, wherein each memory die of the stack in the first test vehicle includes front-end-of-line (FEOL) or middle-of-line (MOL) layers.

14. The proxy device of claim 10, wherein at least one die in the stack of the first test vehicle includes one or more active circuits, and wherein the one or more active circuits are communicably coupled to the base die by interconnect structures within the stack of the first test vehicle.

15. The proxy device of claim 10, wherein the first test vehicle includes a die crack monitor circuit formed in at least one memory die in the stack of memory dies, and wherein the die crack monitor circuit is positioned at least partially around a perimeter of the at least one memory die.

16. The proxy device of claim 10, wherein the first test vehicle includes a high-bandwidth memory device that is a functional reject.

17. A method for testing compatibility of a system-in-package (SiP) device with a package substrate, the method comprising:
forming a device as a proxy for the SiP device, the device including a pair of test vehicles disposed on an interposer and a native communication channel extending between the pair of test vehicles, wherein at least one test vehicle of the pair includes an interface die and a stack of dies disposed over the interface die, and wherein at least one die in the stack is a memory die and includes front-end-of-line (FEOL) and middle-of-line (MOL) layers;
after forming the device, integrating the device with the package substrate;
coupling an external testing device to one or more access pins of the package substrate; and
after integrating the device with the package substrate, assessing compatibility of the SiP device with the package substrate, wherein assessing the compatibility includes executing, using the external testing device, one or more tests involving the pair of test vehicles of the device.

18. The method of claim 17, wherein the pair of test vehicles includes a first test vehicle and a second test vehicle, and wherein executing the one or more tests includes:
transmitting a first value toward the first test vehicle via a first access pin of the one or more access pins;
reading a second value via a second access pin of the one or more access pins; and
comparing the second value to the first value, wherein a mismatch between the first value and the second value indicates an error in a communication path extending (a) between the first access pin and the second access pin and (b) through the first test vehicle, the native communication channel, and the second test vehicle.

19. The method of claim 17, wherein the pair of test vehicles includes a first test vehicle and a second test vehicle, and wherein executing the one or more tests includes:
receiving a first set of data at the first test vehicle;
calculating, at the first test vehicle, a first multiple input signature register (MISR) value based at least in part on the first set of data;
transmitting the first MISR value to the second test vehicle via the native communication channel;
receiving, at the second test vehicle, a second set of data;
calculating, at the second test vehicle, a second MISR value based at least in part on the second set of data; and
comparing the first MISR value to the second MISR value, wherein a mismatch between the first MISR value and the second MISR value indicates integrity of the first test vehicle or the second test vehicle has been compromised.

20. The method of claim 17, wherein executing the one or more tests includes detecting cracks in the interface die or in one or more dies of the stack of the at least one test vehicle.
